(19) United States
(12) Patent Application Publication
(10) Pub. No.: US 2008/0251869 A1
(43) Pub. Date: Oct. 16, 2008

(54) PHOTOSENSITIVE CHIP PACKAGE

(75) Inventor: Tzu-Yin YEN, TAICHUNG COUNTY (TW)

Correspondence Address: BROWDY AND NEIMARK, P.L.L.C.;624 NINTH STREET, NW, SUITE 300, WASHINGTON, DC, 20001-5303, US

(73) Assignee: Lingsen Precision Industries, Ltd., Taichung (TW)

(21) Appl. No.: 11/773,516

(22) Filed: Jul. 5, 2007

(30) Foreign Application Priority Data
Apr. 16, 2007 (TW) 96206090

(51) Int. Cl. H01L 31/0232

(52) U.S. Cl. 257/432; 257/E31.127

(57) ABSTRACT

A photosensitive chip package includes a substrate on which a photosensitive chip having a photo-active zone and a photo-inactive zone surrounding the photo-active zone is bonded. A light-transmissive film covers the photo-active zone of the photosensitive chip. Bonding wires are electrically connected with the photosensitive chip and the substrate. An encapsulant covers the photo-inactive zone of the photosensitive chip, a border periphery of the light-transmissive film and the bonding wires. The encapsulant has an opening corresponding to the photo-active zone. By means of the light-transmissive film, the photo-active zone of the photosensitive chip is protected, thereby lowering the chance of accidental damage to the photosensitive chip by the tool used during formation of the encapsulant and/or during a cleaning work.

### BACKGROUND OF THE INVENTION

1. Field of the Invention

The present invention relates generally to photosensitive chips and more particularly, to a photosensitive chip package using a light-transmissive film to protect a photo-active zone of the photosensitive chip.

2. Description of the Related Art

To enhance the performance and reliability of a photosensitive chip package, mechanical support strength and the problem of interference of light must be taken into account during packaging. Molding technology is commonly employed to package photosensitive chips for the advantage of simplified manufacturing procedure.

During packaging, the photo-active zone of the photosensitive chip is directly exposed outside. Therefore, the photo-active zone of the photosensitive chip may be damaged accidentally during compression molding, resulting in photosensitive chip failure. Further, dust or oil dirt may fall on the photo-active zone of the photosensitive chip during packaging, thereby affecting the performance of the photosensitive chip. Further, after packaging, the photo-active zone of the photosensitive chip of this package structure has many small corners, which are not easy to clean when they are contaminated. A regular non-touch cleaning tool, such as vacuum cleaner, can only remove dust and fine particle. For cleaning oil stains from the photo-active zone of a photosensitive chip, a touch type cleaning tool must be used. However, touching the photo-active zone of a photosensitive chip with a touch type cleaning tool may damage the surface of the photo-active zone.

Therefore, it is desirable to provide a photosensitive chip package that eliminates the aforesaid drawbacks.

### SUMMARY OF THE INVENTION

The present invention has been accomplished in view of the above-noted circumstances. It is therefore one objective of the present invention to provide a photosensitive chip package, which has means to protect the photo-active zone of the photosensitive chip against accidental friction.

To achieve the above-mentioned objective, the photosensitive chip package provided by the present invention comprises a substrate on which a photosensitive chip having a photo-active zone and a photo-inactive zone surrounding the photo-active zone is bonded, a light-transmissive film covering the photo-active zone of the photosensitive chip, a plurality of bonding wires electrically connected with the photosensitive chip and the substrate, and an encapsulant covering the photo-inactive zone of the photosensitive chip, a border periphery of the light-transmissive film and the bonding wires. The encapsulant has an opening corresponding to the photo-active zone.

The photosensitive chip package provided by the present invention uses the light-transmissive film to protect the photo-active zone of the photosensitive chip, thereby lowering the chance of accidental damage to the photosensitive chip by the tool used during formation of the encapsulant and also lowering the chance of accidental friction of the photo-active zone of the photosensitive chip during a cleaning work.

Further, a polarizing layer can be provided on the light-transmissive film to minimize the light interference, thereby enhancing the reliability of the photosensitive chip.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIG. 1 is a schematic drawing showing a sectional view of a photosensitive chip package in accordance with a first preferred embodiment of the present invention;

FIG. 2 is a schematic drawing showing a sectional view of a photosensitive chip package in accordance with a second preferred embodiment of the present invention;

FIG. 3 is a schematic drawing showing a sectional view of a photosensitive chip package in accordance with a third preferred embodiment of the present invention, and

FIG. 4 is a schematic drawing showing a sectional view of a photosensitive chip package in accordance with a fourth preferred embodiment of the present invention.

### DETAILED DESCRIPTION OF THE INVENTION

As shown in FIG. 1, a photosensitive chip package 10 in accordance with a first preferred embodiment of the present invention comprises a substrate 20, a photosensitive chip 30, a light-transmissive film 40, a plurality of bonding wires 50, and an encapsulant 60.

The substrate 20 can be made of epoxy, organic fiber glass substrates, glass fiber board or polyphenylene either. According to this embodiment, the substrate 20 is preferably made of organic fiber glass substrates. Because the technical features of the present invention are not focused on the substrate 20, no further detailed description in this regard is necessary.

The photosensitive chip 30 is installed on the top side of the substrate 20, having a photo-active zone 32 at a center thereof and a photo-inactive zone 34 surrounding the photo-active zone 32. The photosensitive chip 30 according to this embodiment is preferably a CCD (charge-coupled device) chip. However, CCD is just an example, not a limitation.

The light-transmissive film 40 is covered on the top side of the photo-active zone 32. The light-transmissive film 40 can be prepared from a colorless transparent material or any of a variety of transmissive materials having different transmittance subject to actual requirement.

The bonding wires 50 are electrically connected with the substrate 20 and the photosensitive chip 30.

The encapsulant 60 is formed on the substrate 20, covering the photo-inactive zone 34 of the photosensitive chip 30, the border periphery of the light-transmissive film 40 and the bonding wires 50. The encapsulant 60 has an opening 62 corresponding to the photo-active zone 32 so that light can pass through the opening 62 and fall upon the photo-active zone 32.

Subject to the aforesaid arrangement, the photosensitive chip package 10 uses the light-transmissive film 40 to protect the photosensitive chip 30, thereby lowering the chance of accidental damage to the photosensitive chip 30 by the tool used during formation of the encapsulant 60 and also lowering the chance of accidental friction of the photo-active zone 32 during a cleaning work.

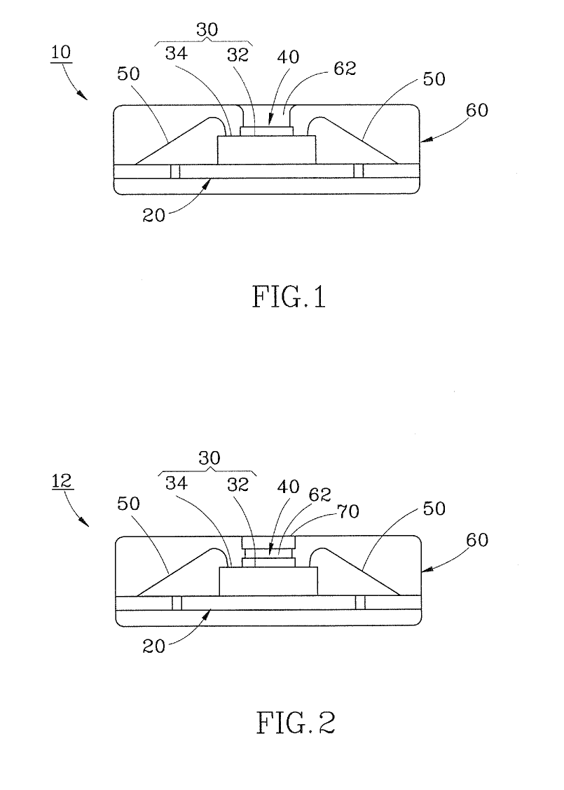

FIG. 2 illustrates a photosensitive chip package 12 in accordance with a second preferred embodiment of the present invention. Similar to the aforesaid first embodiment, the photosensitive chip package 12 comprises a substrate 20, a photosensitive chip 30, a light-transmissive film 40, a plurality of bonding wires 50, and an encapsulant 60. This second embodiment further comprises a light-transmissive glass 70 embedded in the top side of the encapsulant 60 to shield the photo-active zone 32, providing a protection to the photo-active zone 32.

In addition to achieving the same effect of the aforesaid first embodiment, this second embodiment uses the light-transmissive glass 70 to enhance the protection of the photosensitive chip 30.

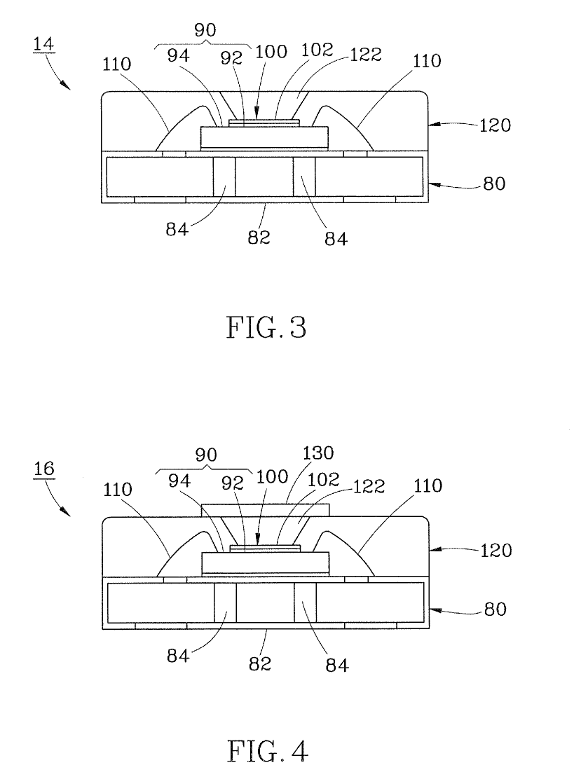

FIG. 3 illustrates a photosensitive chip package 14 in accordance with a third preferred embodiment of the present invention. According to this third embodiment, the photosensitive chip package 14 comprises a photosensitive chip 80, a photo-sensitive chip 90, a light-transmissive film 100, a plurality of bonding wires 110, and an encapsulant 120.

The substrate 80 can be made of epoxy, organic fiber glass substrates, glass fiber board or polyphenylene either. The substrate 80 comprises a heat-dissipative pad 82 and a plurality of heat-dissipative passages 84. The heat-dissipative pad 82 is provided at the bottom side of the substrate 80. The heat-dissipative passages 84 each have one end connected to the photosensitive chip 90 and the other end connected to the heat-dissipative pad 82.

The photosensitive chip 90 is installed on the top side of the substrate 80, having a photo-active zone 92 and a photo-inactive zone 94. The photo-active zone 92 is at the center of the photosensitive chip 90. The photo-inactive zone 94 surrounds the photo-active zone 92. The photosensitive chip 90 according to this embodiment is preferably a CCD (charge-coupled device) chip. However, CCD is just an example, not a limitation.

The light-transmissive film 100 is covered on the top side of the photo-active zone 92. The light-transmissive film 100 can be prepared from a colorless transparent material or any of a variety of transmissive materials having different transmittancy subject to actual requirement. Further, the light-transmissive film 100 has a polarizing layer 102 that allows lightwave to pass through the light-transmissive film 100 in one single direction only and isolates other reflected light or dazzling light, lowering the chance of light interference.

The bonding wires 110 are electrically connected with the photosensitive chip 90 and the substrate 80.

The encapsulant 120 is formed on the top side of the substrate 80, covering the photo-inactive zone 94 of the photosensitive chip 90, the border periphery of the light-transmissive film 100 and the bonding wires 110. The encapsulant 120 has an opening 122 corresponding to the photo-active zone 92 so that light can pass through the opening 122 and fall upon the photo-active zone 92.

In addition to the same protective effect as the aforesaid first embodiment, this third embodiment eliminates the problems of reflected light and dazzling light and improves the heat-dissipative effect of the photosensitive chip 90.

FIG. 4 illustrates a photosensitive chip package 16 in accordance with a fourth preferred embodiment of the present invention. Similar to the aforesaid third embodiment, the photosensitive chip package 16 of this fourth embodiment comprises a photosensitive chip 80, a photo-sensitive chip 90, a light-transmissive film 100, a plurality of bonding wires 110 and an encapsulant 120. The photosensitive chip package 16 of this fourth embodiment further comprises a light-transmissive glass 130 embedded in the top side of the encapsulant 120 to shield the opening 122 of the encapsulant 120, providing a protection to the photo-active zone 92.

In addition to achieving the same effect of the aforesaid third embodiment, this fourth embodiment uses the light-transmissive glass 130 to enhance the protection of the photosensitive chip 90.

As stated above, the present invention uses a light-transmissive film to protect the photosensitive chip, lowering the chance of accidental damage to the photosensitive chip by the tool used during formation of the encapsulant and also lowering the chance of accidental friction of the photo-active zone during a cleaning work. Further, the invention uses a polarizing layer to eliminate light interference, enhancing the reliability of the photosensitive chip.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A photosensitive chip package comprising:
a substrate;
a photosensitive chip bonded on the substrate and having a photo-active zone and a photo-inactive zone surrounding the photo-active zone;
a light-transmissive film covering the photo-active zone of the photosensitive chip;
a plurality of bonding wires electrically connected with the photosensitive chip and the substrate; and
an encapsulant covering the photo-inactive zone of the photosensitive chip, a border periphery of the light-transmissive film and the bonding wires and having an opening corresponding to the photo-active zone.

2. The photosensitive chip package as claimed in claim 1, wherein the light-transmissive film comprises a polarizing layer.

3. The photosensitive chip package as claimed in claim 1, further comprising a light-transmissive glass mounted in the encapsulant for shielding the opening.

4. The photosensitive chip package as claimed in claim 1, wherein the substrate comprises a heat-dissipative pad at a side thereof opposite to the photosensitive chip, and a plurality of heat-dissipative passages each having a first end connected to the photosensitive chip and a second end connected to the heat-dissipative pad.
